(19) United States
(12) Patent Application Publication
(10) Pub. No.: US 2013/0248978 A1
(43) Pub. Date: Sep. 26, 2013

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Takeshi SAKAGUCHI, Mie (JP); Fumitaka Arai, Mie (JP)

(73) Assignee: Kabushiki Kaisha Toshiba, Tokyo (JP)

(21) Appl. No.: 13/837,246

(22) Filed: Mar. 15, 2013

(30) Foreign Application Priority Data
Mar. 22, 2012 (JP) 2012-065681
Aug. 7, 2012 (JP) 2012-175454

(51) Int. Cl. H01L 27/11

(52) U.S. Cl. CPC H01L 27/1104
USPC 257/326; 438/287

(57) ABSTRACT

According to an embodiment, a semiconductor device includes a plurality of first semiconductor regions that extend in a first direction and are arranged in a direction intersecting the first direction, and each element separation region that is provided between the plurality of first semiconductor regions. The element separation region includes a first element separation portion that is formed to a first depth from an upper surface of the first semiconductor region and a second element separation portion that is formed from the first depth to a second depth more than the first depth and electrically insulates between adjacent elements.

### CROSS-REFERENCE TO RELATED APPLICATIONS

This application is based upon and claims the benefit of priority from Japanese Patent Application No. 2012-65681, filed on Mar. 22, 2012, and the prior Japanese Patent Application No. 2012-175454, filed on Aug. 7, 2012; the entire contents of all of which are incorporated herein by reference.

### FIELD

Embodiments described herein relate generally to a semiconductor device and a method of manufacturing the same.

### BACKGROUND

In a non-volatile semiconductor memory device as represented by NAND-type flash memory, with scaling, an element separation region is formed to a predetermined depth to electrically insulate between elements. However, there is a trade-off relationship between the scaling of the non-volatile semiconductor memory device and the securing of the electrical insulation.

### BRIEF DESCRIPTION OF THE DRAWINGS

FIG. 1 is an example of a schematic plan view illustrating a non-volatile semiconductor memory device according to a first embodiment;

FIG. 2A is an example of a schematic cross-sectional view corresponding to a cross-section taken along the line A-A′ of FIG. 1;

FIG. 2B is an example of a schematic cross-sectional view corresponding to a cross-section taken along the line B-B′ of FIG. 1;

FIGS. 3A, 4A, 5A, 6A, 7A, 8A, 9A, 10A, and 11A are examples of schematic cross-sectional views illustrating a process of manufacturing the non-volatile semiconductor memory device according to the first embodiment;

FIGS. 3B, 4B, 5B, 6B, 7B, 8B, 9B, 10B, and 11B are examples of schematic plan views illustrating the process of manufacturing the non-volatile semiconductor memory device according to the first embodiment;

FIGS. 12A and 12B are examples of schematic cross-sectional views illustrating the operation of the non-volatile semiconductor memory device according to the first embodiment;

FIG. 13A is an example of a schematic cross-sectional view illustrating a non-volatile semiconductor memory device according to a second embodiment which corresponds to the cross-section taken along the line A-A′ of FIG. 1;

FIG. 13B is an example of a schematic cross-sectional view illustrating the non-volatile semiconductor memory device according to the second embodiment which corresponds to the cross-section taken along the line B-B′ of FIG. 1;

FIGS. 14A to 14C are examples of schematic cross-sectional views illustrating a process of manufacturing the non-volatile semiconductor memory device according to the second embodiment;

FIG. 15 is an example of a schematic cross-sectional view illustrating a non-volatile semiconductor memory device according to a modification of the second embodiment;

FIG. 16 is an example of a cross-sectional view taken along taken along the line B-B′ of FIG. 1;

FIG. 17 is an example of a cross-sectional view taken along taken along the line B-B′ of FIG. 1;

FIGS. 18A to 18H are examples of cross-sectional views schematically illustrating an example of the procedure of a method of manufacturing a semiconductor device according to a third embodiment;

FIG. 19 is an example of a cross-sectional view schematically illustrating the structure of a NAND-type flash memory device when diffusion is not sufficient;

FIGS. 20A and 20B are diagrams illustrating an example of the simulation result of an impurity concentration distribution when a channel semiconductor layer and a punch-through suppression layer are formed by an ion implantation method and a thermal diffusion method; and

FIGS. 21A and 21B are diagrams illustrating an example of the simulation result of an impurity concentration distribution when a channel semiconductor layer and a punch-through suppression layer are formed by a method according to the third embodiment.

### DETAILED DESCRIPTION

In general, according to an embodiment, a semiconductor device includes a plurality of first semiconductor regions that extend in a first direction and are arranged in a direction intersecting the first direction and each element separation region that is provided between the plurality of first semiconductor regions. The element separation region includes a first element separation portion that is formed to a first depth from an upper surface of the first semiconductor region and a second element separation portion that is formed from the first depth to a second depth more than the first depth and electrically insulates between adjacent elements.

Hereinafter, a semiconductor device and a method of manufacturing the same according to embodiments will be described in detail with reference to the accompanying drawings. The invention is not limited by the embodiments. The cross-sectional views of the semiconductor devices used in the following embodiments are schematic. In the cross-sectional views, in some cases, the relationship between the thickness and width of each layer or the scale of the thickness of each layer is different from the actual relationship or scale.

Next, a case in which the embodiment is applied to a NAND-type flash memory device will be described. The NAND-type flash memory device includes a memory cell region in which a plurality of memory cell transistors (hereinafter, referred to as memory cells) are arranged in a matrix and a peripheral circuit region including peripheral circuit transistors for driving the memory cells.

### First Embodiment

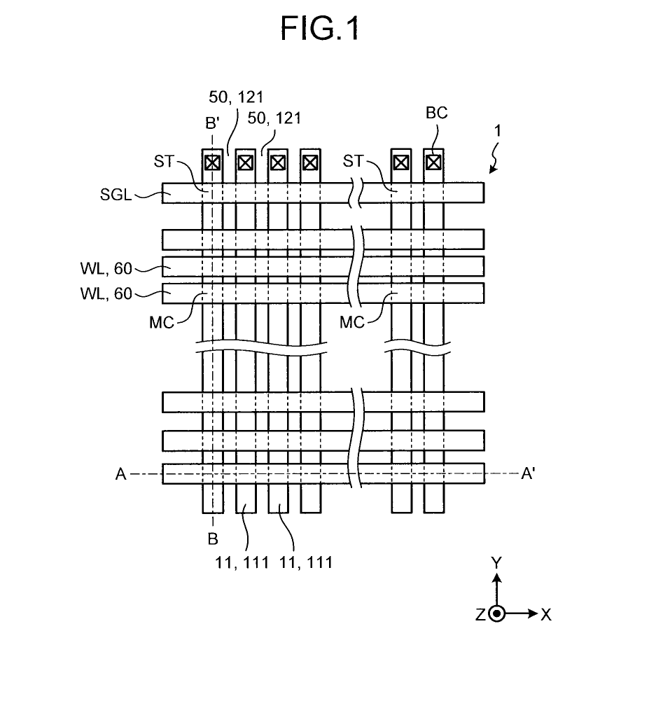

FIG. 1 is an example of a plan view schematically illustrating a non-volatile semiconductor memory device according to a first embodiment. FIG. 1 illustrates the planar layout of a memory cell unit of NAND-type flash memory.

A non-volatile semiconductor memory device 1 according to the first embodiment includes a plurality of semiconductor regions 11 (first semiconductor regions) and a plurality of control gate electrodes 60 (WL). The plurality of semiconductor regions 11 (first semiconductor regions or channel semiconductor layers 111 serving as active regions) extend in a Y direction (first direction) and are arranged in a direction intersecting the Y direction, for example, a direction (X direction) substantially perpendicular to the Y direction. The plurality of control gate electrodes 60 extend in the X direction (second direction) different from the Y direction and are arranged in a direction intersecting the X direction, for example, a direction (Y direction) substantially perpendicular to the X direction. The plurality of control gate electrodes 60 are provided above the plurality of semiconductor regions 11, which will be described below. In the non-volatile semiconductor memory device 1, the plurality of semiconductor regions 11 intersect the plurality of control gate electrodes 60.

Each of the plurality of semiconductor regions 11 forms a portion of a NAND string. The plurality of semiconductor regions 11 are separated from each other by each element separation region 50 (element separation insulating film), such as an STI (Shallow Trench Isolation) 121 which is arranged between adjacent semiconductor regions 11. The element separation regions extend in the Y direction and are arranged at predetermined intervals in the X direction. The control gate electrode 60 may be referred to as a word line WL.

In the non-volatile semiconductor memory device 1, transistors are arranged at the intersections of the plurality of semiconductor regions 11 and the plurality of control gate electrodes 60 (which will be described below). The transistors are two-dimensionally arranged in the X direction and the Y direction. Each transistor functions as a memory cell MC of the non-volatile semiconductor memory device 1. A pair of select gate lines SGL which extends in the X direction similarly to the word lines WL are arranged at the end of a predetermined number of word lines WL in the Y direction, and select gate transistors ST are formed at the intersections of the semiconductor regions 11 and the select gate lines SGL. In FIG. 1, only one select gate line SGL is illustrated. In addition, a bit line contact BC is provided so as to be connected to an impurity diffusion region, which is a source/drain region of the select gate transistor ST.

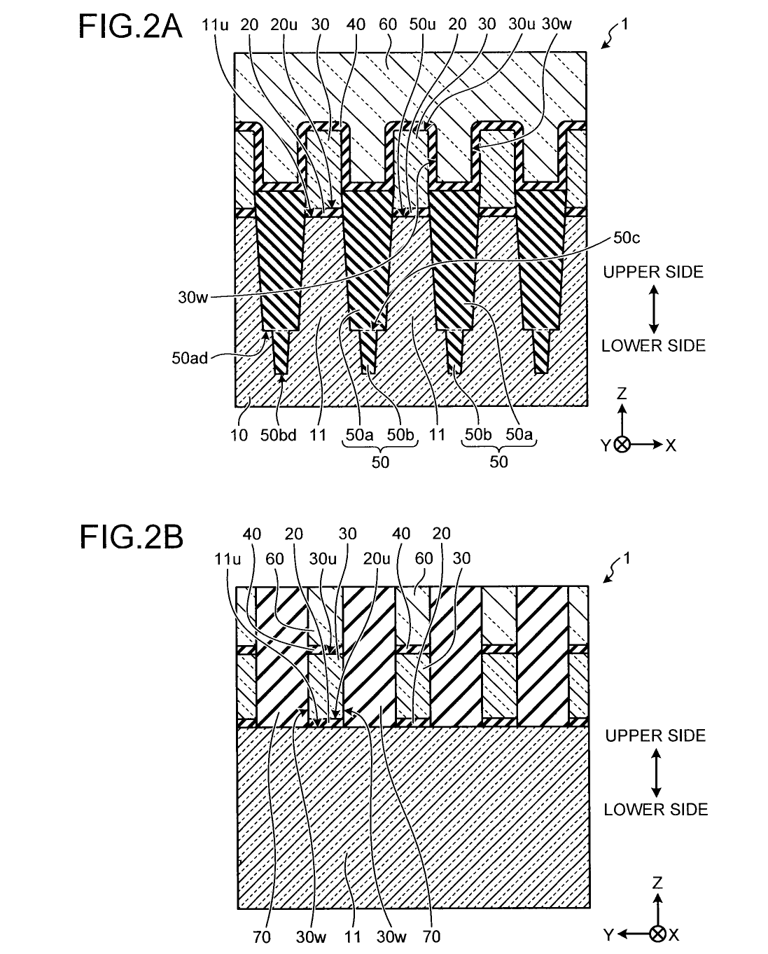

FIGS. 2A and 2B are examples of schematic cross-sectional views illustrating the non-volatile semiconductor memory device according to the first embodiment. FIG. 2A is an example of a schematic cross-sectional view corresponding to the cross-section taken along the line A-A′ of FIG. 1 and FIG. 2B is an example of a schematic cross-sectional view corresponding to the cross-section taken along the line B-B′ of FIG. 1. In FIGS. 2A and 2B, the positive direction of the Z-axis indicates the upward direction and the negative direction thereof indicates the downward direction.

The non-volatile semiconductor memory device 1 includes a gate insulating film 20 (first gate insulating film), a charge trapping layer 30, a gate insulating film 40 (second gate insulating film), and the element separation region 50, in addition to the semiconductor regions 11 and the control gate electrodes 60. The non-volatile semiconductor memory device 1 includes transistors each of which includes the semiconductor region 11, the gate insulating film 20, the charge trapping layer 30, the gate insulating film 40, and the control gate electrode 60 and which are arranged at the intersections of the semiconductor regions 11 and the control gate electrodes 60.

Each of the plurality of semiconductor regions 11 is defined by the element separation region 50 in a semiconductor substrate 10. For example, each of the plurality of semiconductor regions 11 which extend in the Y direction is defined by the element separation region 50 in the semiconductor substrate 10 (FIG. 2A). Each of the plurality of semiconductor regions 11 functions as an active region which is occupied by the transistor of the non-volatile semiconductor memory device 1.

The gate insulating film 20 is provided between the charge trapping layer 30 and the semiconductor region 11. An upper surface 20u of the gate insulating film 20 is lower than an upper surface 50u of the element separation region 50. The gate insulating film 20 functions as a tunnel insulating film that allows charge (for example, an electron) to tunnel between the semiconductor region 11 and the charge trapping layer 30.

The charge trapping layer 30 is provided at the intersection of each of the plurality of semiconductor regions 11 and each of the plurality of control gate electrodes 60. The charge trapping layer 30 covers the upper surface 20u of the gate insulating film 20. The charge trapping layer 30 can store the charge which tunnels through the gate insulating film 20 from the semiconductor region 11. The charge trapping layer 30 may be referred to as a floating gate layer. Since the charge trapping layer 30 has a rectangular shape extending in the Z direction in the cross-sectional views of FIGS. 2A and 2B respectively taken along the line A-A′ and the line B-B′, it has a prismatic shape extending in the Z direction.

The gate insulating film 40 is provided between the charge trapping layer 30 and the control gate electrode 60. The gate insulating film 40 covers an upper surface 30u of the charge trapping layer 30. For example, the gate insulating film 40 covers at least a portion of the charge trapping layer 30 except for a portion of the charge trapping layer 30 which comes into contact with the element separation region 50, in the Y direction (FIG. 2A). In other words, the gate insulating film 40 covers a portion of a side surface 30w of the charge trapping layer 30 in the Y direction. In addition, the side surface 30w of the charge trapping layer 30 is covered by an interlayer insulating film 70 in the X direction (FIG. 2B).

That is, the upper surface 30u and the side surface 30w of the charge trapping layer 30 are covered by an insulator such that the charge stored in the charge trapping layer 30 does not leak to the control gate electrode 60. The gate insulating film 40 may be referred to as a charge blocking layer.

The control gate electrode 60 covers a portion of the charge trapping layer 30 with the gate insulating film 40 interposed therebetween. For example, the control gate electrode 60 covers portions of the upper surface 30u and the side surface 30w of the charge trapping layer 30, with the gate insulating film 40 interposed therebetween, in the Y direction (FIG. 2A). In addition, the control gate electrode 60 covers the upper surface 30u of the charge trapping layer 30, with the gate insulating film 40 interposed therebetween, in the X direction (FIG. 2B). The control gate electrode 60 functions as a gate electrode for controlling the transistor.

Each element separation region 50 is provided between the plurality of semiconductor regions 11. The element separation region 50 comes into contact with the gate insulating film 20 and the charge trapping layer 30. The element separation regions 50 electrically separate the plurality of semiconductor regions 11. The upper surface 50u of the element separation region 50 is lower than the upper surface 30u of the charge trapping layer 30. An upper surface 11u of the semiconductor region 11 is lower than the upper surface 50u of the element separation region 50.

The element separation region 50 includes a first element separation portion 50a and a second element separation portion 50b which is provided below the first element separation portion 50a. The width of the second element separation portion 50b in the X direction at a position 50c where the first element separation portion 50a and the second element separation portion 50b are connected to each other is less than the width of the first element separation portion 50a in the X direction at the position 50c. That is, there is a difference in level between the first element separation portion 50a and the second element separation portion 50b in the X direction at the position 50c.

A length from the interface between the upper surface 30u of the charge trapping layer 30 and the gate insulating film 40 to a lower end 50ad of the first element separation portion 50a is less than a length from the interface between the upper surface 30u of the charge trapping layer 30 and the gate insulating film 40 to a lower end 50bd of the second element separation portion 50b (FIG. 2A).

The semiconductor substrate 10 (or the semiconductor region 11) is made of, for example, a P-type (first conduction type) semiconductor crystal. An example of the semiconductor is silicon (Si).

The gate insulating film 20 is made of, for example, a silicon oxide (SiO₂) or a silicon nitride (Si₃N₄). The gate insulating film 20 may be, for example, a single layer, such as a silicon oxide film or a silicon nitride film, or a stacked film including the silicon oxide film or the silicon nitride film.

The charge trapping layer 30 may be made of, for example, a semiconductor material, such as Si or a Si-based compound, a material (for example, metal or an insulating film) other than the semiconductor material, or a stacked film thereof. The material forming the charge trapping layer 30 is, for example, a semiconductor including an N-type (second conduction type) impurity, metal, or a metal compound. Examples of the material include amorphous silicon (a-Si), polysilicon (poly-Si), silicon germanium (SiGe), silicon nitride (SiₓN_{y}), and hafnium oxide (HfOx).

The gate insulating film 40 may be, for example, a single layer, such as a silicon oxide film or a silicon nitride film, or a stacked film including the silicon oxide film or the silicon nitride film. For example, the gate insulating film 40 may be a so-called ONO film (a silicon oxide film/a silicon nitride film/a silicon oxide film). In addition, the gate insulating film 40 may be a metal oxide film or a metal nitride film.

The element separation region 50 and the interlayer insulating film 70 are made of, for example, a silicon oxide (SiO₂).

The control gate electrode 60 is made of, for example, a semiconductor including an N-type impurity. An example of the semiconductor is polysilicon. Alternatively, the control gate electrode 60 may be made of, for example, a metal material, such as tungsten, or metal silicide.

In the embodiment, the P type is the first conduction type and the N type is the second conduction type. However, the N type may be the first conduction type and the P type may be the second conduction type. An example of the P-type impurity element is boron (B). An example of the N-type impurity element is phosphorus (P) or arsenic (As).

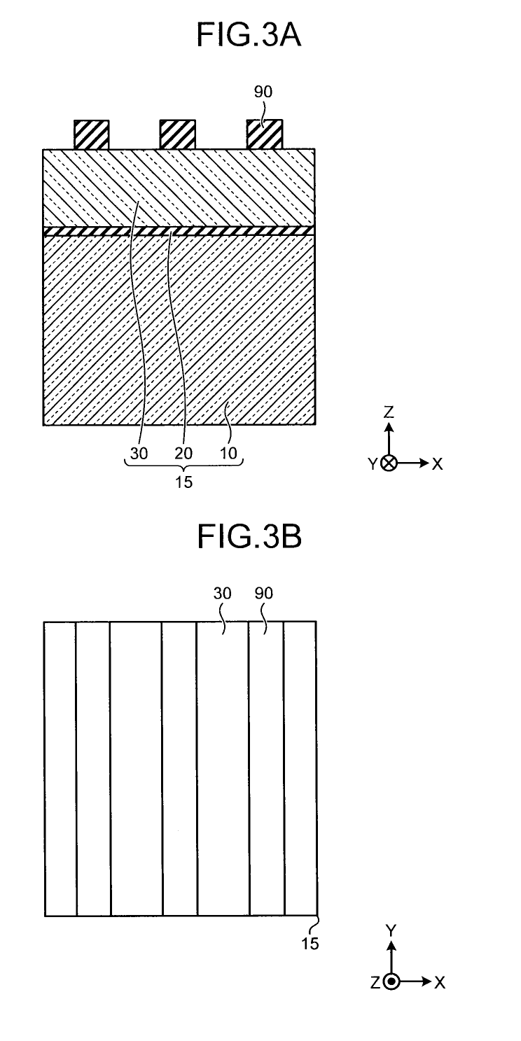

A process of manufacturing the non-volatile semiconductor memory device 1 will be described below. FIGS. 3A to 11B are examples of diagrams illustrating a process of manufacturing the non-volatile semiconductor memory device according to the first embodiment. FIGS. 3A, 4A, 5A, 6A, 7A, 8A, 9A, 10A, and 11A are cross-sectional views taken along the line A-A′ of FIG. 1 and FIGS. 3B, 4B, 5B, 6B, 7B, 8B, 9B, 10B, and 11B are top views.

As illustrated in FIGS. 3A and 3B, a plurality of mask layers 90 which extend in the Y direction and are arranged in a direction intersecting the Y direction, for example, a direction (X direction) substantially perpendicular to the Y direction are formed on a stacked body 15. The stacked body 15 includes the P-type semiconductor substrate (semiconductor layer) 10, the gate insulating film 20 which is provided on the semiconductor substrate 10, and the charge trapping layer 30 which is provided on the gate insulating film 20.

The mask layers 90 are patterned by, for example, photolithography and etching. The mask layer 90 is made of a material with high processing selectivity with respect to a semiconductor. For example, the mask layer 90 is made of, a silicon oxide (SiO₂), a silicon nitride (Si₃N₄), a resist, other materials, or a stacked structure thereof.

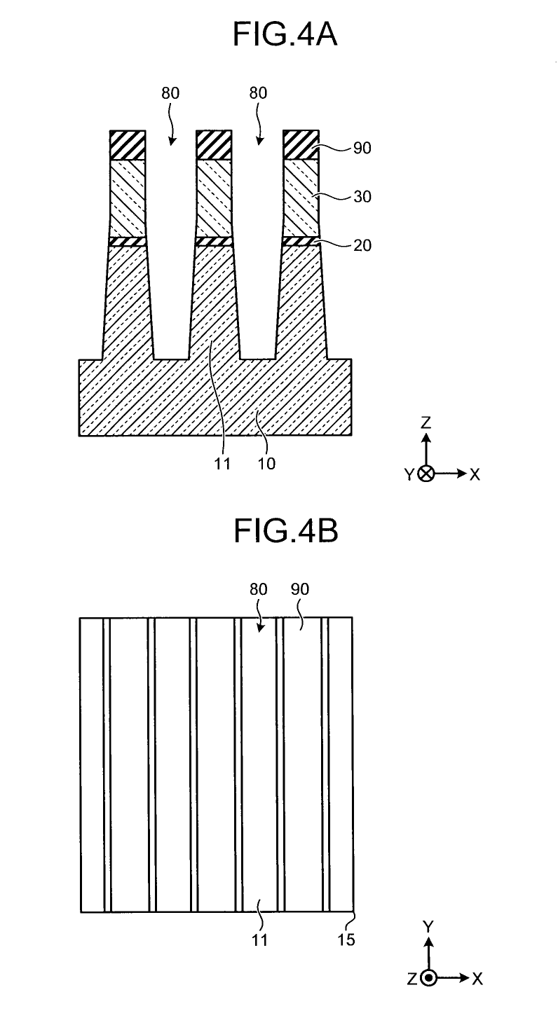

As illustrated in FIGS. 4A and 4B, a first etching process is performed for a portion of the stacked body 15 exposed from the plurality of mask layers 90. The etching method is, for example, RIE (Reactive Ion Etching). In this way, a plurality of trenches 80 which extend in the Y direction are formed on the semiconductor substrate 10 and the semiconductor region 11 interposed between the plurality of trenches 80 are formed. With the formation of the semiconductor region 11, the gate insulating film 20 which extends in the Y direction is formed on the semiconductor region 11 and the charge trapping layer 30 which extends in the Y direction is formed on the gate insulating film 20.

In the first etching process, the trench 80 is formed such that the stacked body 15 including the semiconductor region 11, the gate insulating film 20, and the charge trapping layer 30 does not collapse.

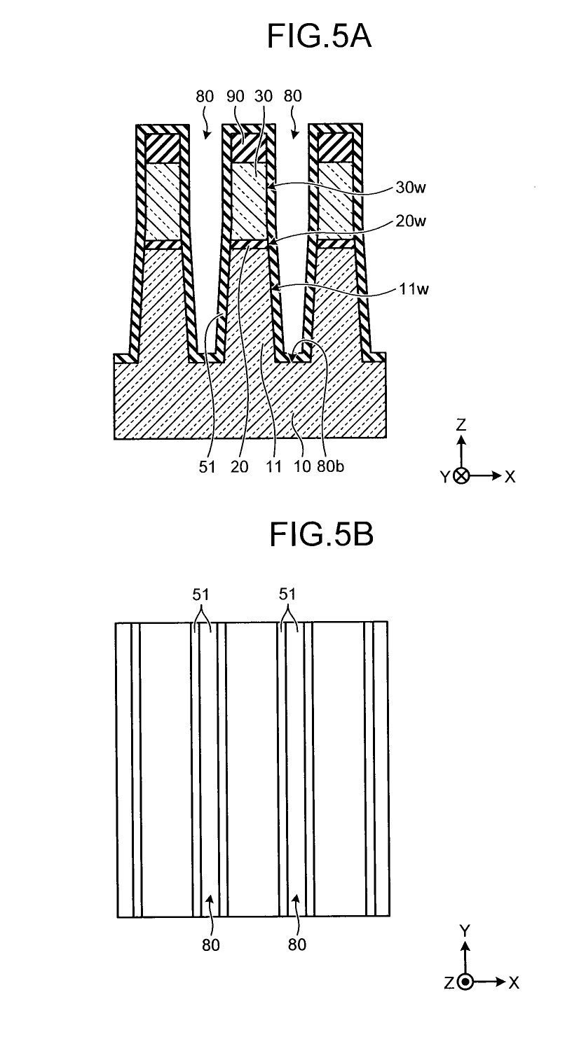

As illustrated in FIGS. 5A and 5B, an insulating layer 51 is formed on the bottom 80b of the trench 80, a side surface 11w of the semiconductor region 11, a side surface 20w of the gate insulating film 20, the side surface 30w of the charge trapping layer 30, and an exposure surface of the mask layer 90. The insulating layer 51 is formed by, for example, CVD (Chemical Vapor Deposition).

The insulating layer 51 is formed on the bottom 80b of the trench 80, the side surface 11w of the semiconductor region 11, the side surface 20w of the gate insulating film 20, the side surface 30w of the charge trapping layer 30, and the exposure surface of the mask layer 90 at the same time. Therefore, the insulating layer 51 is seamlessly formed on the side surface 11w of the semiconductor region 11, the side surface 20w of the gate insulating film 20, and the side surface 30w of the charge trapping layer 30, and the semiconductor region 11, the gate insulating film 20, and the charge trapping layer 30 are supported by the continuous insulating layer 51.

In the first embodiment, for example, a silicon oxide (SiO₂) is selected as the material forming the insulating layer 51. Alternatively, a material with high selectivity (the etching speed of the layer to be etched/the etching speed of a mask layer) in an RIE process, which will be described below, may be selected as the material forming the insulating layer 51. For example, a silicon nitride (Si₃N₄) is selected as the material. In addition, a material other than the above or a stack of the materials may be selected as the material forming the insulating layer 51.

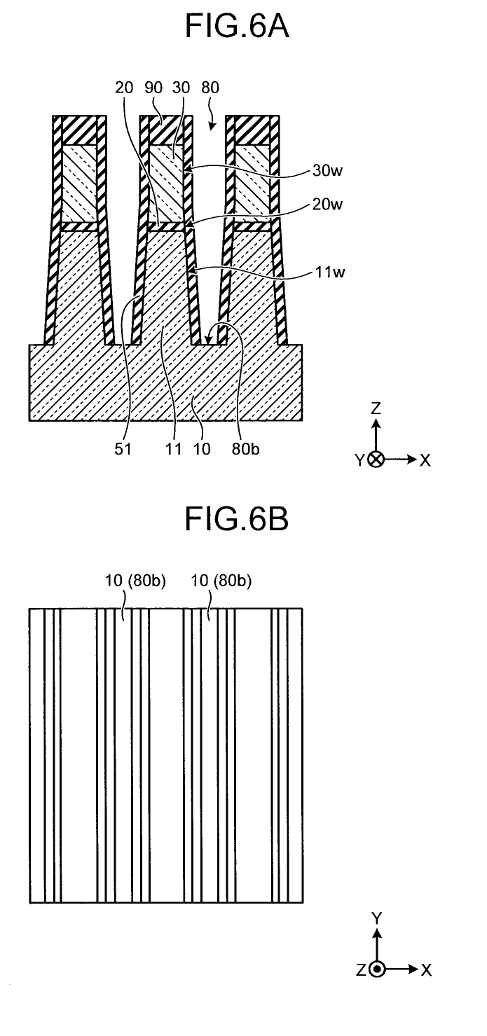

As illustrated in FIGS. 6A and 6B, anisotropic etching is performed for the insulating layer 51 to selectively remove the insulating layer 51 provided on the bottom 80b of the trench 80.

In this way, the insulating layer 51 is formed on the side surface 11w of the semiconductor region 11, the side surface 20w of the gate insulating film 20, and the side surface 30w of the charge trapping layer 30. In this stage, the semiconductor substrate 10 is exposed from the bottom 80b of the trench 80.

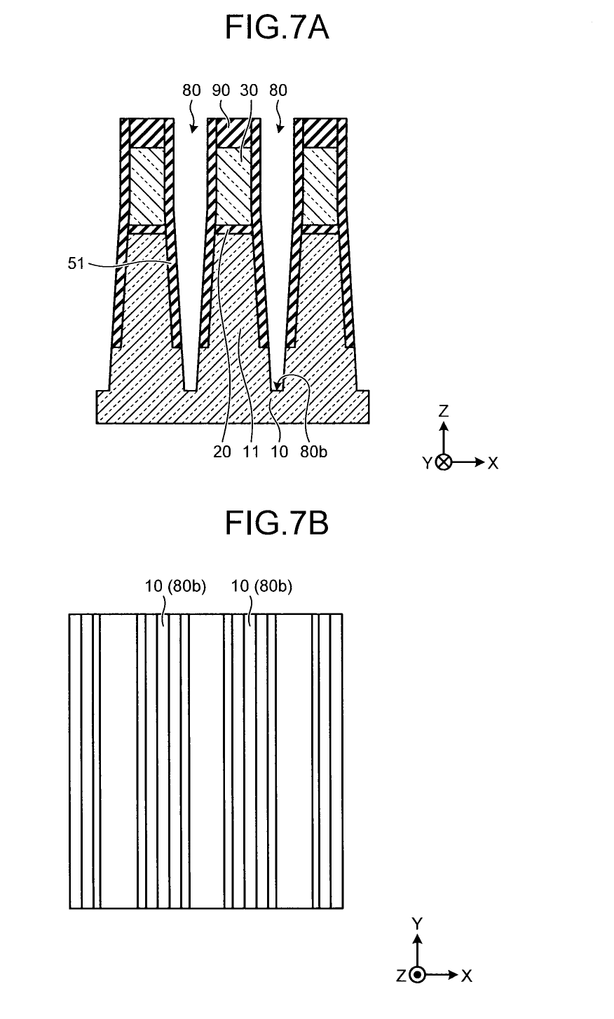

Then, a second etching process is performed for the semiconductor substrate 10 below the bottom 80b of each of the plurality of trenches 80 and the bottom 80b of each of the plurality of trenches 80 is further lowered. The etching method is, for example, RIE. This state is illustrated in FIGS. 7A and 7B.

As illustrated in FIGS. 7A and 7B, the depth of the trench 80 increases. In the RIE process, the insulating layer 51 functions as a mask layer for the semiconductor region 11, the gate insulating film 20, and the charge trapping layer 30, and the semiconductor region 11, the gate insulating film 20, and the charge trapping layer 30 are less likely to be damaged by etching.

The width of the trench 80, which is formed downward from the lower end of the insulating layer 51, in the X direction is less than the width of the trench 80, which is formed upward from the lower end of the insulating layer 51, in the X direction due to the insulating layer 51.

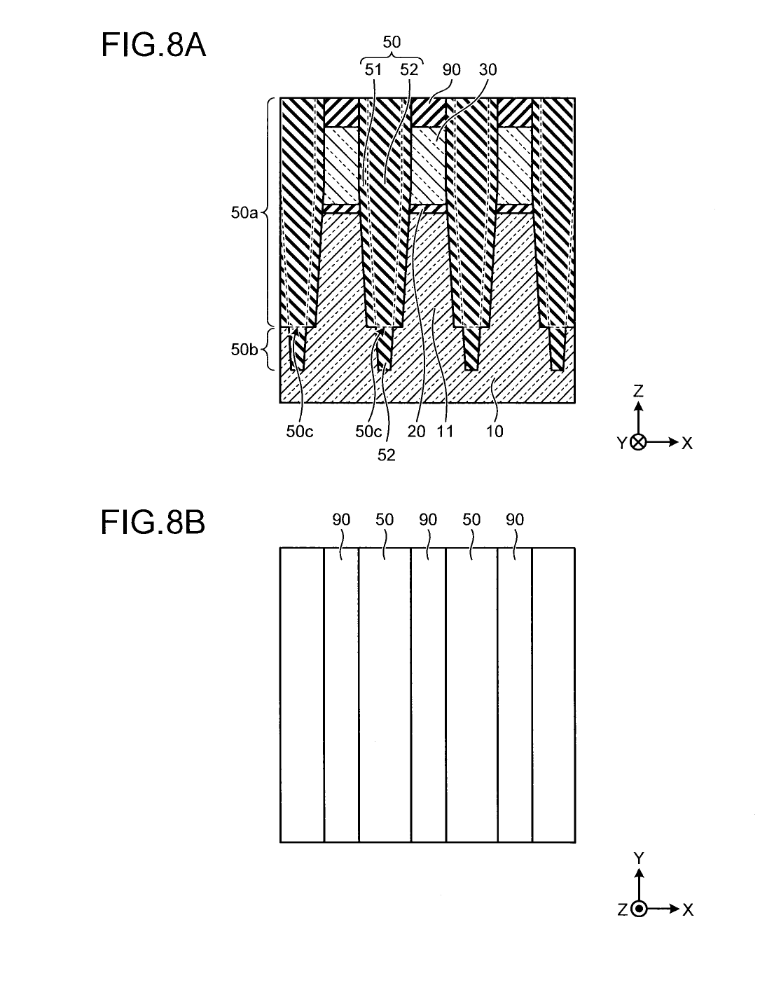

As illustrated in FIGS. 8A and 8B, an insulating layer 52 is formed in each of the plurality of trenches 80. The insulating layer 52 is formed by, for example, CVD. The insulating layer 52 is made of, for example, a silicon oxide (SiO₂). When the insulating layer 51 and the insulating layer 52 are made of the same insulating material, there is practically no boundary between the insulating layer 51 and the insulating layer 52 after the insulating layer 52 is formed on the insulating layer 51. That is, the element separation region 50 in which the insulating layer 51 and the insulating layer 52 are integrated with each other is formed in each of the plurality of trenches 80. When the insulating layer 51 and the insulating layer 52 are made of different materials, the element separation region 50 includes a layer made of the material forming the insulating layer 51 and a layer made of the material forming the insulating layer 52.

The insulating layer 51 is interposed between the insulating layer 52, and the semiconductor region 11, the first gate insulating film 20, and the charge trapping layer 30.

FIGS. 2A and 2B illustrate a state in which the element separation region 50 is divided in the depth direction of the trench 80. Since the trench 80 is formed by two-stage etching, the element separation region which is formed upward from the lower end of the insulating layer 51 is the first element separation portion 50a and the element separation region which is formed downward from the lower end of the insulating layer 51 is the second element separation portion 50b. That is, the element separation region 50 includes the first element separation portion 50a and the second element separation portion 50b.

The first element separation portion 50a includes the insulating layer 51 and a portion of the insulating layer 52 and the second element separation portion 50b includes portions of the insulating layer 52 other than the portion included in the first element separation portion 50a. Therefore, the width of the second element separation portion 50b in the X direction at the position 50c where the first element separation portion 50a and the second element separation portion 50b are connected to each other is less than the width of the first element separation portion 50a in the X direction at the position 50c.

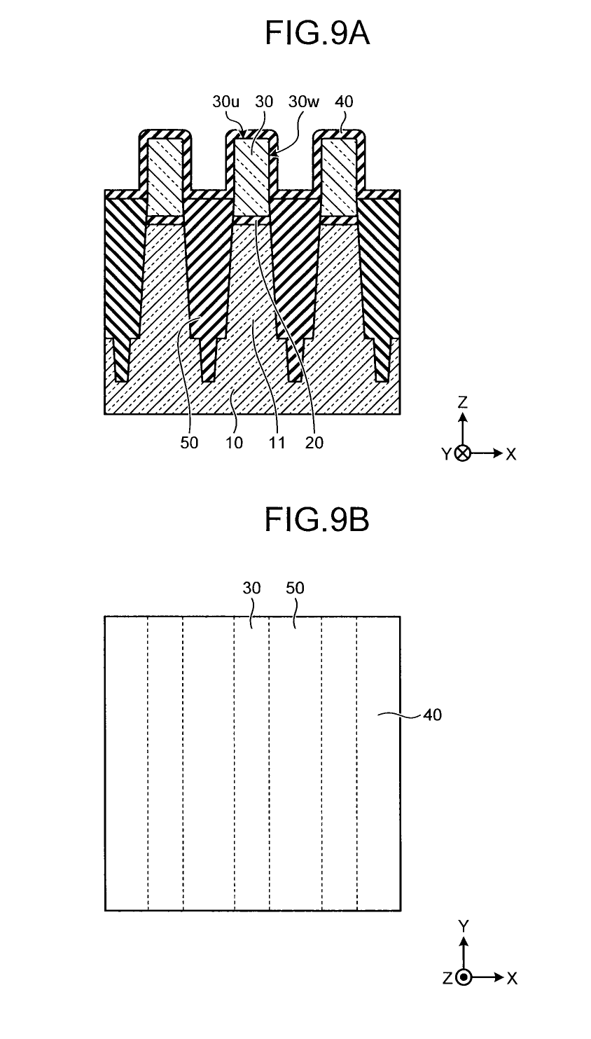

Then, etching is performed for the mask layer 90 and the element separation region 50 to expose the upper surface 30u of the charge trapping layer 30 and a portion of the side surface 30w thereof. In addition, the gate insulating film 40 is formed on the exposed surface of the charge trapping layer 30. This state is illustrated in FIGS. 9A and 9B. The mask layer 90 may not be completely removed, but may be used as a portion of the gate insulating film 40.

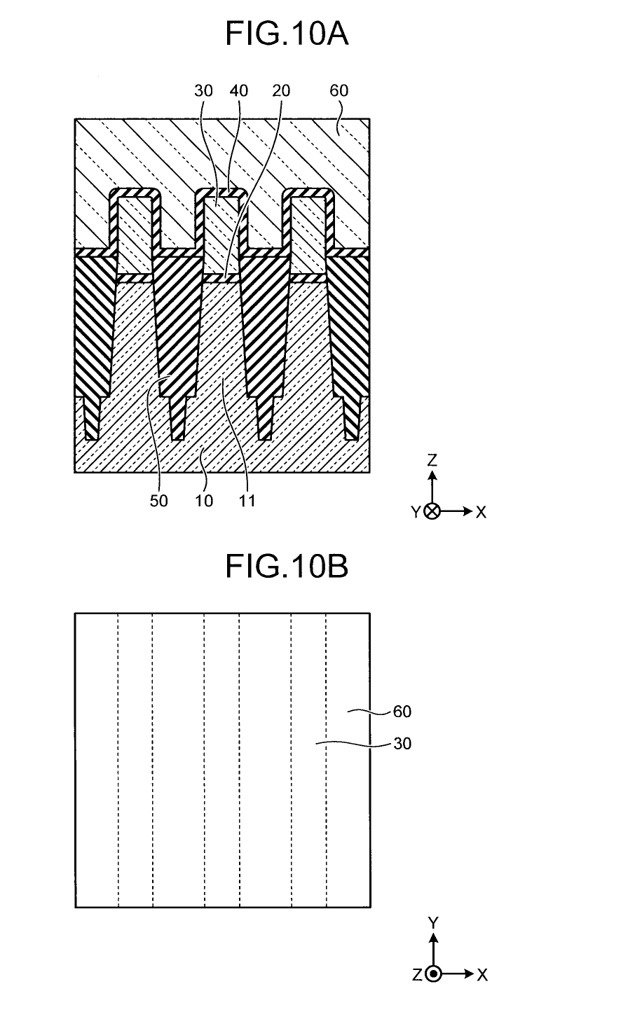

As illustrated in FIGS. 10A and 10B, the control gate electrode 60 is formed on the gate insulating film 40.

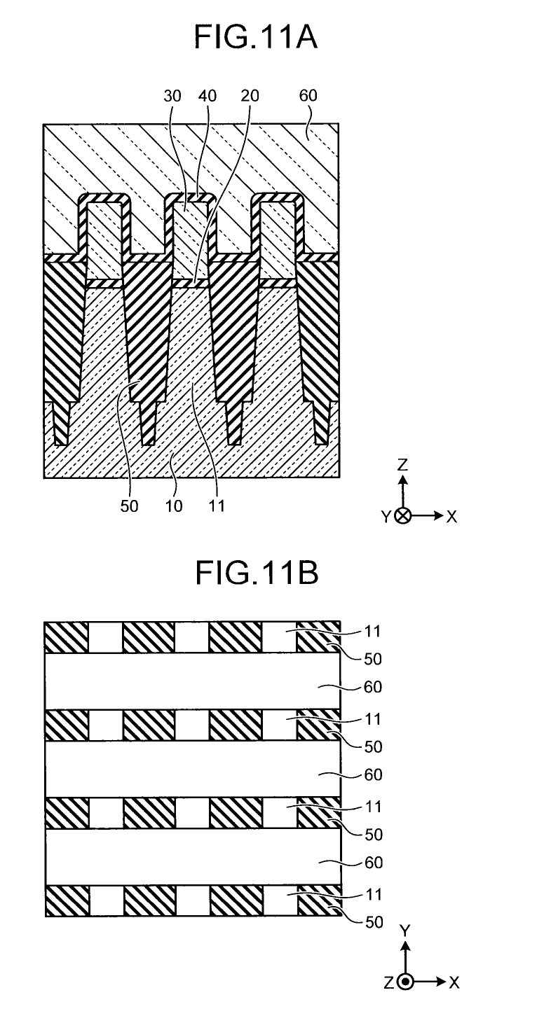

As illustrated in FIGS. 11A and 11B, the control gate electrode 60 is divided in the Y direction by photolithography and etching to form a plurality of control gate electrodes 60 extending in the X direction. Then, the interlayer insulating film 70 is formed between the plurality of control gate electrodes 60 (not illustrated). The non-volatile semiconductor memory device 1 is formed by the above-mentioned manufacturing process.

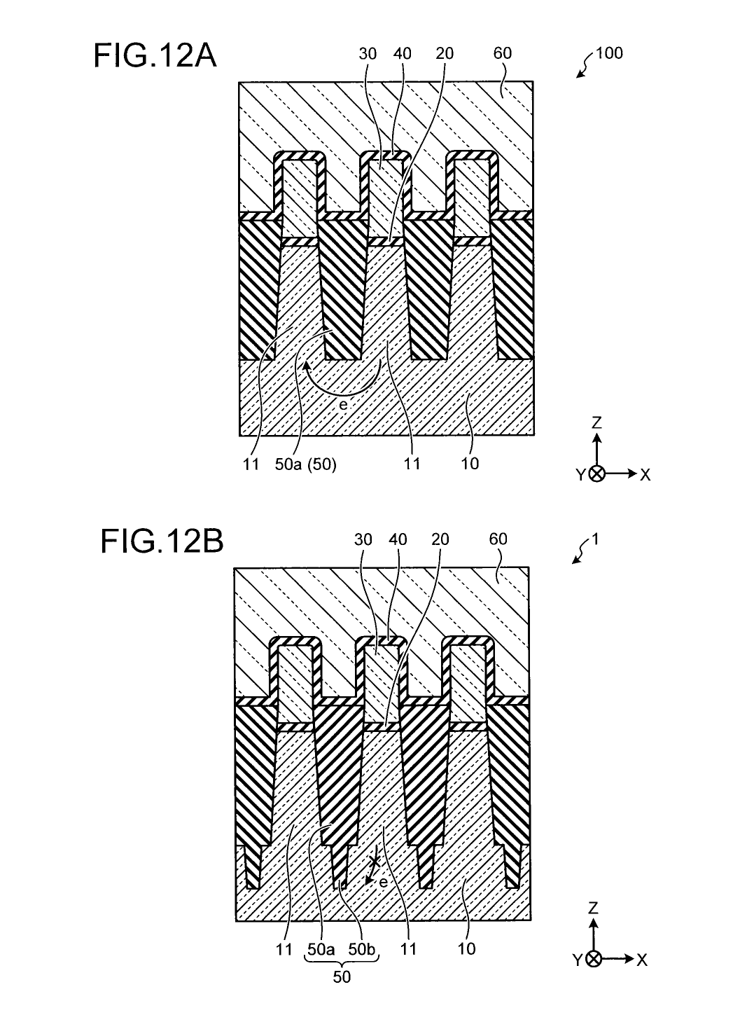

FIGS. 12A and 12B are schematic cross-sectional views illustrating the operation of the non-volatile semiconductor memory device according to the first embodiment. FIG. 12A is a cross-sectional view illustrating a non-volatile semiconductor memory device 100 which does not include the second element separation portion 50b, but includes only the first element separation portion 50a. In the non-volatile semiconductor memory device 100, the first element separation portion 50a is the element separation region 50.

However, when the non-volatile semiconductor memory device 100 is shrunk, the distance between the plurality of semiconductor regions 11 is reduced and a so-called punch-through current (e) is likely to flow under the bottom of the element separation region 50. This is because sufficient insulation is not ensured only by the first element separation portion 50a with the scaling of the element.

In contrast, the non-volatile semiconductor memory device 1 according to the first embodiment illustrated in FIG. 12B includes the first element separation portion 50a and the second element separation portion 50b provided below the first element separation portion 50a. Therefore, in the non-volatile semiconductor memory device 1, the length of the element separation region in the Z direction is more than that in the non-volatile semiconductor memory device 100 in FIG. 12A. As a result, in the non-volatile semiconductor memory device 1, the electrical insulation between the plurality of semiconductor regions 11 is further improved and the punch-through current (e) is less likely to flow between the plurality of semiconductor regions 11. Therefore, the reliability of the non-volatile semiconductor memory device 1 is higher than that of the non-volatile semiconductor memory device 100 in FIG. 12A.

When the insulating layer 51 and the insulating layer 52 are made of the same material, a difference in stress between the insulating layer 51 and the insulating layer 52 is less likely to occur. Therefore, there is no stress in the element separation region 50 due to the insulating layer 51 and the insulating layer 52 and peeling from the semiconductor region 11 of the element separation region 50 is less likely to occur. When a silicon oxide is selected as the material forming the insulating layer 51, the electron trap effect of the insulating layer 51 is less than that when a silicon nitride is selected as the material. Therefore, the threshold voltage of each transistor is less likely to vary.

There is a trade-off relationship between the scaling of the non-volatile semiconductor memory device and the securing of electrical insulation. In the first embodiment, a trench etching process for forming the element separation region 50 is divided into the first etching process and the second etching process to dissolve the trade-off relationship.

For example, in the first embodiment, after the trench 80 is formed by the first etching process, the side surface 11w of the semiconductor region 11, the side surface 20w of the gate insulating film 20, and the side surface 30w of the charge trapping layer 30 are protected by the insulating layer 51. In the first etching process, the trench 80 is formed such that a stacked body of the semiconductor region 11, the gate insulating film 20, and the charge trapping layer 30 does not collapse. Then, the trench 80 is etched by the second etching process such that the depth thereof increases. Then, the element separation region 50 is formed in the deep trench 80.

During the second etching process, the side surface of the stacked body is supported by the insulating layer 51. Therefore, the stacked body is less likely to collapse. Since the stacked body is less likely to collapse, the trench 80 is less likely to be blocked by the stacked body. Thus, in each of the plurality of trenches 80, the element separation region is sufficiently filled. As a result, the manufacturing yield of the non-volatile semiconductor memory device is improved.

According to the manufacturing method of the first embodiment, even when the non-volatile semiconductor memory device is shrunk and the aspect ratio of the stacked body increases, the side surface of the stacked body is supported by the insulating layer 51. Therefore, the stacked body is less likely to collapse. In addition, since the element separation region 50 is formed in the deep trench 80 which is formed in two stages, the electrical insulation between the plurality of semiconductor regions 11 is improved. As such, according to the first embodiment, both the scaling and the securing of electrical insulation are achieved.

### Second Embodiment

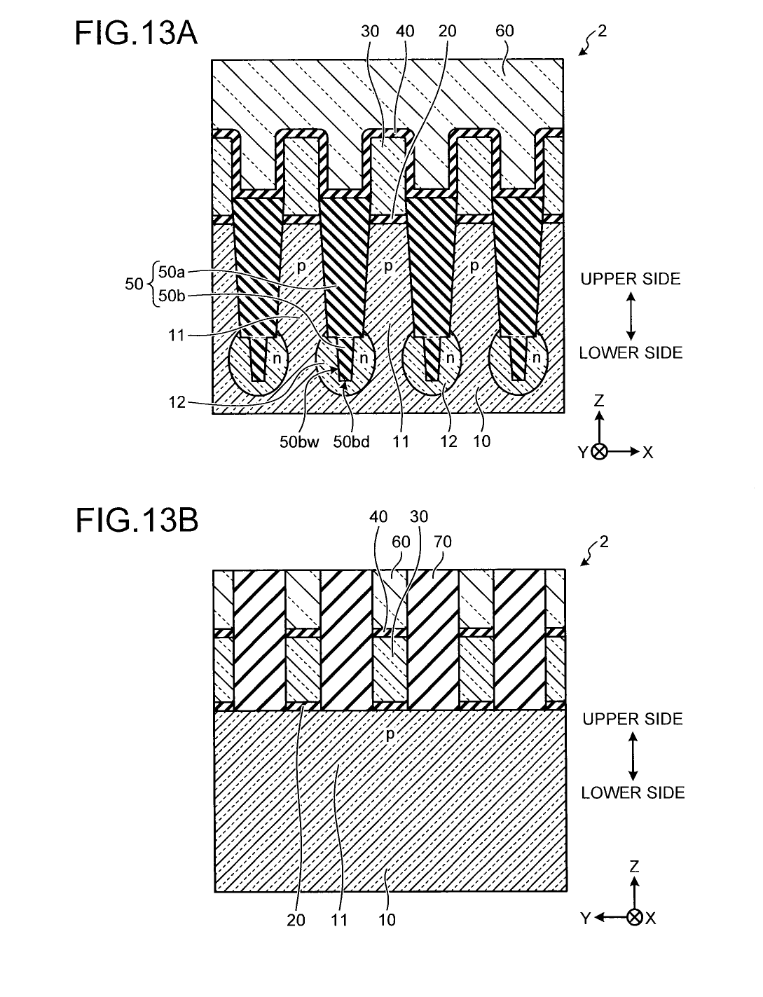

FIGS. 13A and 13B are examples of cross-sectional views illustrating a non-volatile semiconductor memory device according to a second embodiment. FIG. 13A is an example of a schematic cross-sectional view corresponding to the cross-section taken along the line A-A′ of FIG. 1 and FIG. 13B is an example of a schematic cross-sectional view corresponding to the cross-section taken along the line B-B′ of FIG. 1.

A non-volatile semiconductor memory device 2 according to the second embodiment has the same basic structure as the non-volatile semiconductor memory device 1. The non-volatile semiconductor memory device 2 includes a semiconductor region 12 (second semiconductor region) in addition the components of the non-volatile semiconductor memory device 1. The semiconductor region 12 covers at least a portion of a lower end 50bd of an element separation region 50 (second element separation portion 50b) and a side surface 50bw of the element separation region 50 (second element separation portion 50b) connected to the lower end 50bd. The conduction type of the semiconductor region 12 is different from that of a first semiconductor region 11. The conduction type of the semiconductor region 12 is, for example, an N type and the conduction type of the first semiconductor region 11 is, for example, a P type.

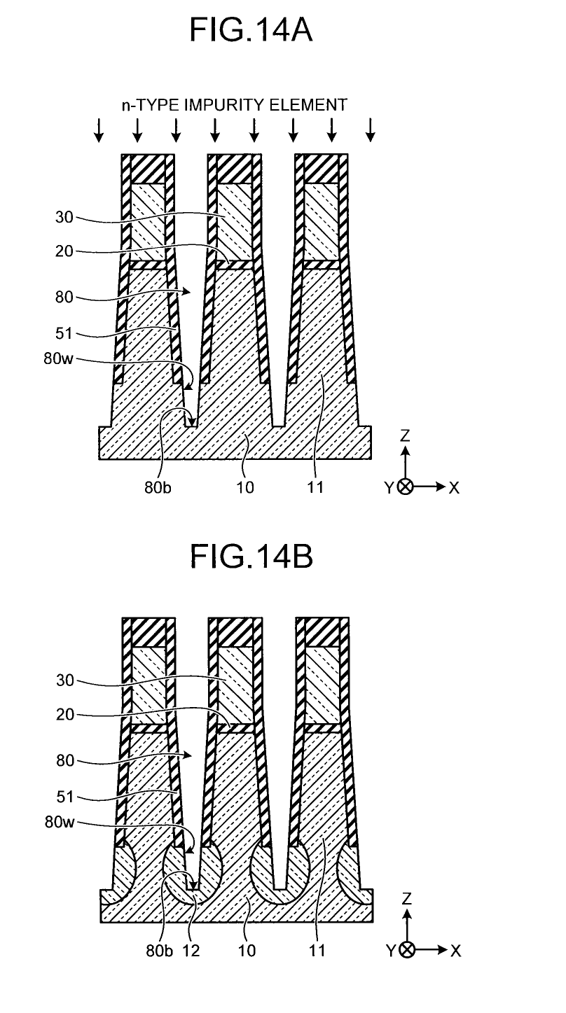

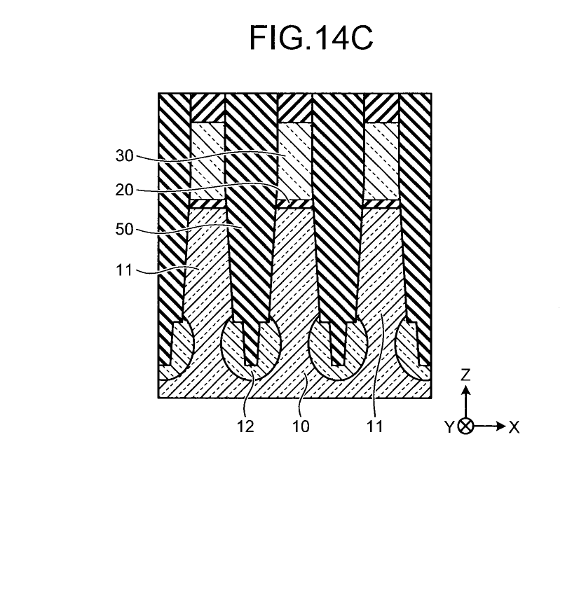

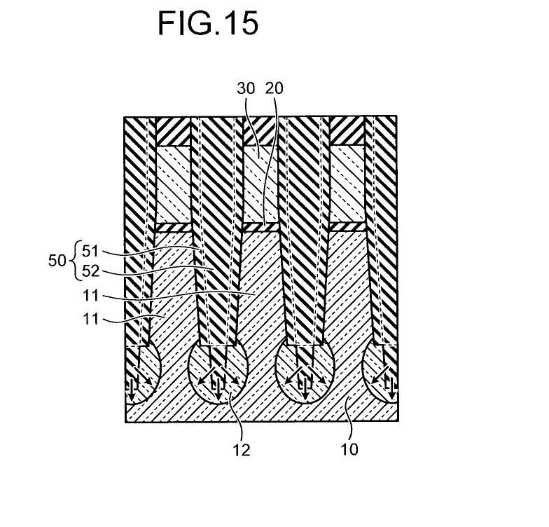

FIGS. 14A to 14C are examples of schematic cross-sectional views illustrating a process of manufacturing the non-volatile semiconductor memory device according to the second embodiment.

For example, after the bottom 80b of each of a plurality of trenches 80 is lowered as illustrated in FIG. 14A, an N-type impurity element is introduced into the semiconductor substrate 10 from a portion of the bottom 80b of each of the plurality of trenches 80 and the side surface 80w of each of the plurality of trench 80 which is connected to the bottom 80b. For example, the N-type impurity element (for example, phosphorus (P) or arsenic (As)) is introduced into the semiconductor substrate 10 by ion implantation. The conduction type of a portion of the semiconductor substrate 10 into which the N-type impurity element is implanted is a P type before the N-type impurity element is implanted. However, in the impurity implantation, the N-type impurity element is implanted such that the conduction type of the portion of the semiconductor substrate 10 is reversed.

When the impurity element is implanted, an insulating layer 51 covers a side surface 11w of the semiconductor region 11 above the lower end of the insulating layer 51, a side surface 20w of a gate insulating film 20, and a side surface 20w of a charge trapping layer 30. Therefore, the N-type impurity element is not implanted into a portion of the semiconductor region 11 above the lower end of the insulating layer 51, the gate insulating film 20, and the charge trapping layer 30. After the N-type impurity element is implanted into the semiconductor substrate 10, the semiconductor substrate 10 is heated. This state is illustrated in FIG. 14B.

As illustrated in FIG. 14B, the semiconductor region 12 is formed between a portion of the bottom 80b and the side surface 80w of the trench 80 and the semiconductor region 11. Then, as illustrated in FIG. 14C, an insulating layer 52 is formed in the trench 80 and the element separation region 50 is formed in the trench 80.

In the second embodiment, the same effect as that in the first embodiment is obtained. In addition, in the non-volatile semiconductor memory device 2 according to the second embodiment, each N-type semiconductor region 12 is provided between the plurality of P-type semiconductor regions 11. That is, in the non-volatile semiconductor memory device 2, each element separation region 50 is provided between the plurality of semiconductor regions 11 and each potential barrier is formed between the plurality of semiconductor regions 11 by PN junction. Therefore, a punch-through current (e) is less likely to flow between the plurality of semiconductor regions 11 and the reliability of the non-volatile semiconductor memory device 2 is further improved.

(Modifications of Second Embodiment)

FIG. 15 is an example of a schematic cross-sectional view illustrating a process of manufacturing a non-volatile semiconductor memory device according to a modification of the second embodiment.

The semiconductor region 12 can be formed by a method other than ion implantation. For example, as illustrated in FIG. 15, the insulating layer 52 including the N-type impurity element is formed in each of the plurality of trenches 80 and the N-type impurity element is thermally diffused from the insulating layer 52 to the semiconductor substrate 10. In this way, the N-type impurity element is introduced into the semiconductor substrate 10.

When the impurity element is introduced, the insulating layer 51 covers the side surface 11w of the semiconductor region 11 above the lower end of the insulating layer 51, the side surface 20w of the gate insulating film 20, and the side surface 30w of the charge trapping layer 30. The insulating layer 51 may not include the N-type impurity element. Therefore, the N-type impurity element is not implanted into a portion of the semiconductor region 11 about the lower end of the insulating layer 51, the gate insulating film 20, and the charge trapping layer 30. This embodiment is also included in the second embodiment.

### Third Embodiment

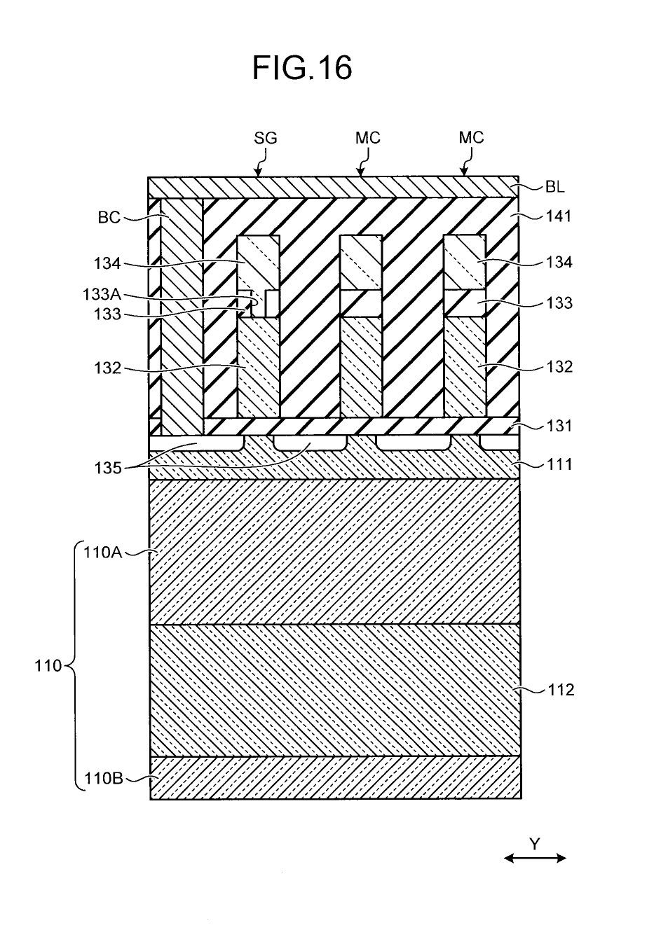

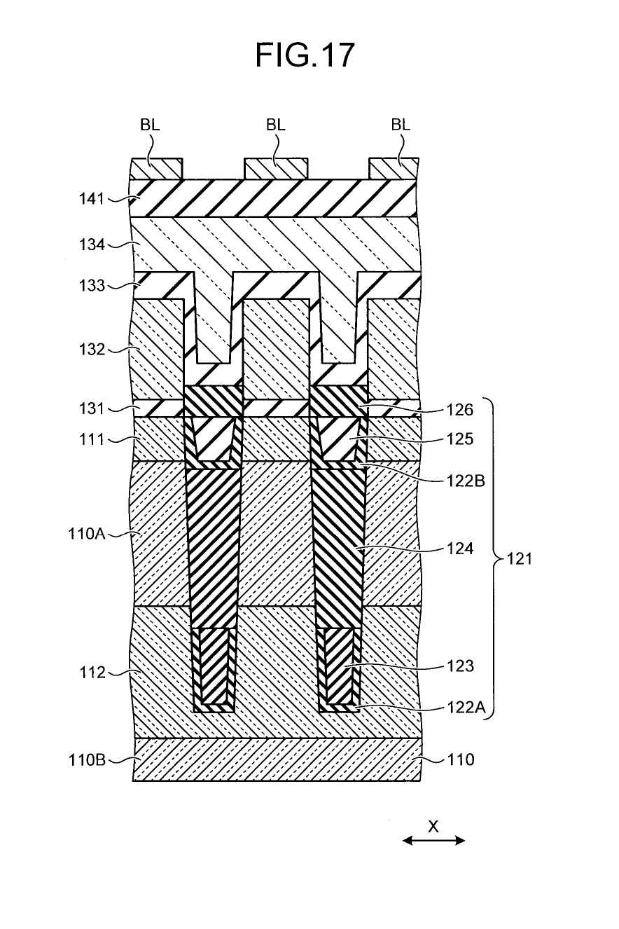

FIG. 16 is an example of a cross-sectional view taken along the line of B-B′ of FIG. 1 and FIG. 17 is an example of a cross-sectional view taken along the line of A-A′ of FIG. 1. First, as illustrated in FIG. 16, in the cross-section taken along the Y direction, a select gate transistor ST and a memory cell MC are connected to each other on a P-type single-crystalline silicon substrate 110, which is a semiconductor substrate, while sharing a source/drain region in the Y direction.

The memory cell MC has a stacked gate structure in which a charge trapping layer 132, a gate insulating film (inter-electrode insulating film) 133, and a control gate electrode 134 are sequentially formed on the silicon substrate 110 with a gate insulating film (tunnel insulating film) 131 interposed therebetween. The select gate transistor ST has a gate structure in which the charge trapping layer 132, the gate insulating film 133, and the control gate electrode 134 are sequentially formed on the silicon substrate 110 with the gate insulating film 131 interposed therebetween and the control gate electrode 134 is embedded in an opening 133a which is formed in the gate insulating film 133 in the thickness direction.

An impurity diffusion region 135 serving as the source/drain region is formed in the vicinity of the surface of a channel semiconductor layer 111 between the stacked gate structures which are adjacent to each other in the Y direction or between the stacked gate structure and the gate structure.

As illustrated in FIG. 17, in the cross-section taken along the X direction on the word line WL, an STI 121 which insulates memory cells MC adjacent to each other in the X direction is provided on the silicon substrate 110. The stacked gate structure of the charge trapping layer 132, the gate insulating film 133, and the control gate electrode 134 are formed on a region of the silicon substrate 110 partitioned by the STI 121, with the gate insulating film 131 interposed therebetween. However, in the cross-section taken along the X direction, the charge trapping layers 132 are separated between the memory cells MC which are adjacent to each other in the X direction, but the gate insulating film 133 and the control gate electrode 134 are commonly connected between the memory cells MC. As such, the word line WL is formed by the control gate electrode 134 which is commonly connected between the memory cells MC which are adjacent to each other in the X direction. The interface between the gate insulating film 131 and the charge trapping layer 132 is lower than the interface between the STI 121 and the gate insulating film 133. The cross-section taken along the X direction on the select gate line SGL has the same structure as described above, which is not illustrated in the drawings.

An interlayer insulating film 141 is formed on the silicon substrate 110 on which the stacked gate structure and the gate structure are formed and bit lines BL which extend in the Y direction are provided on the interlayer insulating film 141. As illustrated in FIG. 16, the bit line BL is connected to the impurity diffusion region 135 of the select gate transistor ST which is provided at one end of a row of the memory cells MC connected in series to each other by a bit line contact BC which is provided so as to pass through the interlayer insulating film 141.

For example, a thermally-oxidized film, a thermally-oxynitrided film, a CVD oxide film, a CVD-oxynitrided film, an insulating film having Si interposed therebetween, or an insulating film having Si embedded in a dot shape may be used as the gate insulating film 131. For example, the following may be used as the charge trapping layer 132: a polycrystalline silicon film doped with an N-type impurity or a P-type impurity; a metal film or a polymetal film made of, for example, Mo, Ti, W, Al, or Ta; a nitride film; and an ONO (Oxide-Nitride-Oxide) film having a stacked structure of a silicon oxide film and a silicon nitride film. For example, the following may be used as the gate insulating film 133: a silicon oxide film; a silicon nitride film; an aluminum oxide film; and a hafnium oxide film. For example, the following may be used as the control gate electrode 134: a polycrystalline silicon film doped with an N-type impurity or a P-type impurity; a metal film or a polymetal film made of, for example, Mo, Ti, W, Al, or Ta; a nitride film; and a film having a stacked structure of a silicon oxide film and a silicon nitride film.

As illustrated in FIGS. 16 and 17, the channel semiconductor layer 111 with a higher P-type impurity concentration than the silicon substrate 110 is formed at a predetermined depth from the upper surface of the P-type silicon substrate 110, and a punch-through suppression layer 112 which has a higher P-type impurity concentration than the silicon substrate 110 and suppresses punch-through is formed in the vicinity of the lower side of the STI 121. In addition, P-type wells 110A and 110B with a lower P-type impurity concentration than the channel semiconductor layer 111 or the punch-through suppression layer 112 are formed between the channel semiconductor layer 111 and the punch-through suppression layer 112 and below the punch-through suppression layer 112.

The STI 121 is basically formed by an insulating film, such as a silicon oxide film, and has a layer structure corresponding to the layer structure of the silicon substrate 110. When the STI 121 is formed by the silicon oxide film, a diffusion source layer 123, which is a silicon oxide film with a predetermined P-type impurity concentration, is formed in a region corresponding to the formation region of the punch-through suppression layer 112 in the lower part of the STI 121 and a diffusion source layer 125, which is a silicon oxide film with a predetermined P-type impurity concentration, is formed in a region corresponding to the formation region of the channel semiconductor layer 111. In addition, insulating layers 124 and 126, which are silicon oxide films without a P-type impurity or with a lower P-type impurity concentration than the diffusion source layers 123 and 125, are formed in a region corresponding to the formation region of the P-type well 110A and above the diffusion source layer 125. Liner films 122A and 122B, which are silicon oxide films without a P-type impurity or with a lower P-type impurity concentration than the diffusion source layers 123 and 125, are formed between the diffusion source layers 123 and 125 and the silicon substrate 110. The thickness of the liner films 122A and 122B is, for example, several nanometers. In addition, the liner films 122A and 122B may not be provided. The liner films may be provided between the insulating layers 124 and 126 and the silicon substrate 110.

The diffusion source layers 123 and 125 are P-type impurity diffusion sources when the punch-through suppression layer 112 and the channel semiconductor layer 111 are formed, which will be described below. According to this structure, it is possible to obtain a concentration distribution in which the concentration of the P-type impurity is precipitously changed at the interfaces between the channel semiconductor layer 111, the P-type well 110A, the punch-through suppression layer 112, and the P-type well 110B on the silicon substrate 110.

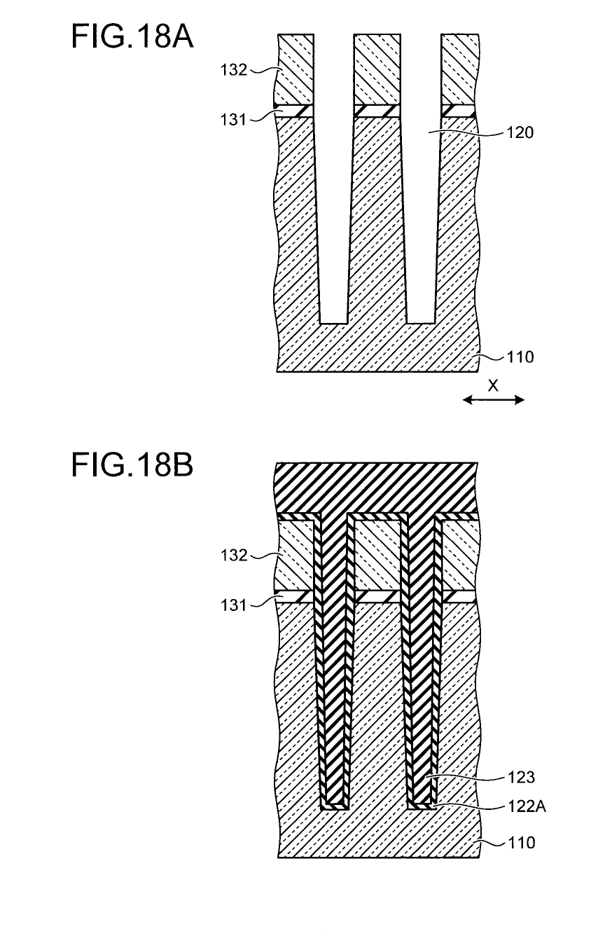

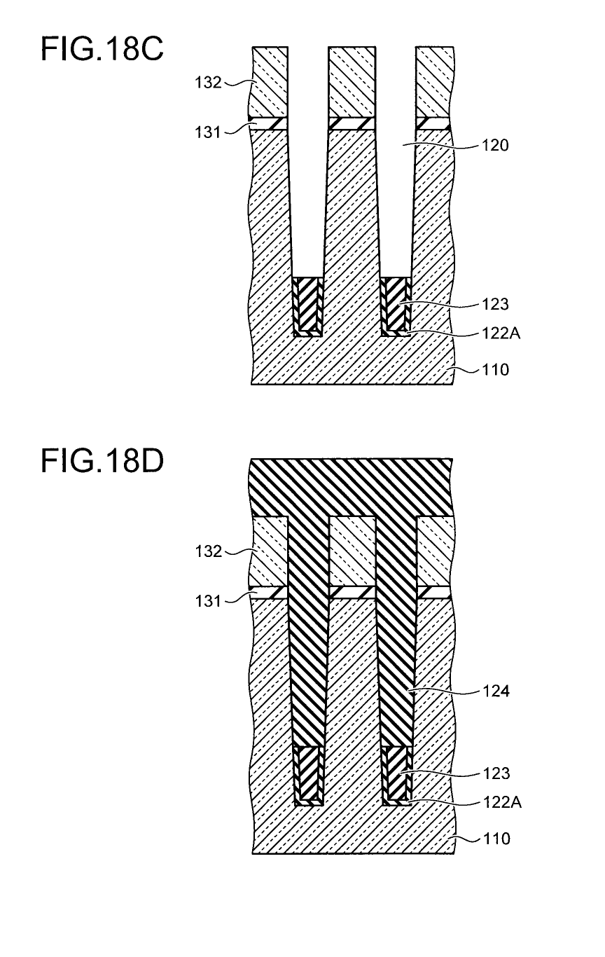

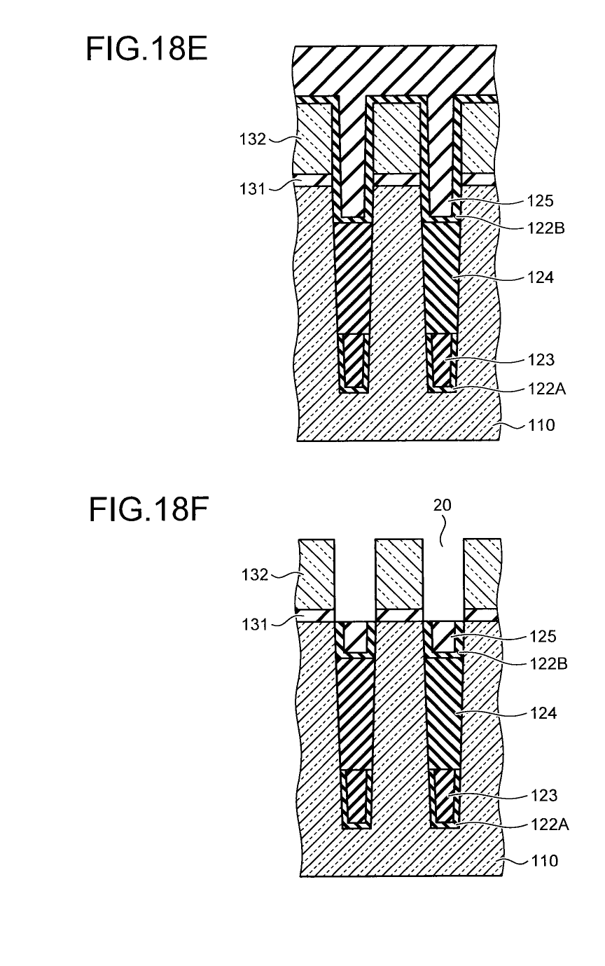

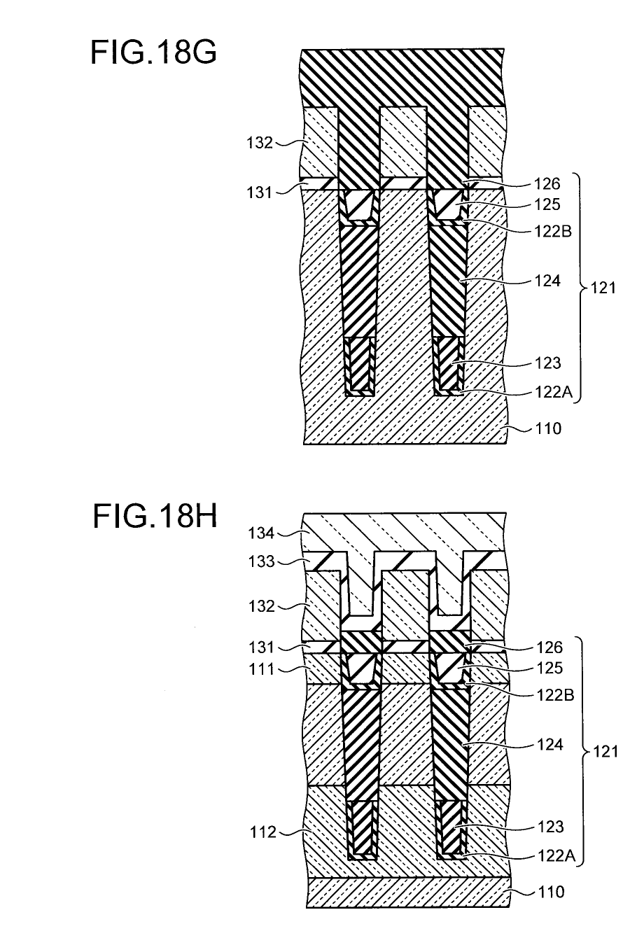

Next, a method of manufacturing the semiconductor device having the above-mentioned structure will be described. FIGS. 18A to 18H are cross-sectional views schematically illustrating an example of the procedure of the method of manufacturing the semiconductor device according to the embodiment. Here, the cross-section taken along the line A-A′ of FIG. 1 will be described as an example.

As illustrated in FIG. 18A, the gate insulating film 131 and the charge trapping layer 132 are formed on the upper surface of the P-type silicon substrate 110 and trenches 120 are formed to a predetermined depth in the silicon substrate 110 by a photolithography technique and an etching technique such as an RIE method. The trenches 120 extend in the Y direction (bit line direction) and are formed at predetermined intervals in the X direction (word line direction). Before the trenches 120 are formed, a P-type impurity is not additionally diffused to regions corresponding to the punch-through suppression layer and the channel semiconductor layer in the silicon substrate 110.

As illustrated in FIG. 18B, the liner film 122A is conformally formed so as to cover the side surface and the bottom of the trench 120. For example, an insulating film, such as a silicon oxide film which has a thickness of several nanometers and does not include an impurity or includes a little impurity, may be used as the liner film 122A. The liner film 122A can be formed by a film forming method such as a CVD method.

In addition, the diffusion source layer 123 with a higher P-type impurity concentration than the silicon substrate 110 is formed on the liner film 122A. The diffusion source layer 123 is formed such that it is embedded in the trench 120 whose inner surface is covered with the liner film 122A and is higher than the upper surface of the charge trapping layer 132. For example, a silicon oxide film including B may be used as the diffusion source layer 123. In addition, the diffusion source layer 123 can be formed by a film forming method such as a CVD method.

The diffusion source layer 123 functions as a P-type impurity diffusion source from which the P-type impurity is diffused to the silicon substrate 110 by a heat treatment which is performed in the subsequent process to form a punch-through suppression layer in a region around the diffusion source layer 123. The P-type impurity concentration of the diffusion source layer 123 is calculated in advance by experiments such that a punch-through suppression layer with desired concentration is finally obtained by diffusion.

As illustrated in FIG. 18C, overall etching is performed by an etching method, such as an RIE method, to remove the diffusion source layer 123 and the liner film 122A such that the diffusion source layer 123 remains to a predetermined depth in the trench 120. The diffusion source layer 123 remains to the depth at which the punch-through suppression layer is formed in the silicon substrate 110.

As illustrated in FIG. 18D, the insulating layer 124, which is, for example, a silicon oxide film without an impurity or with a little impurity, is formed in the trench 120 having the liner film 122A and the diffusion source layer 123 remaining on the bottom thereof so as to be higher than the upper surface of the charge trapping layer 132. As the insulating layer 124, for example, a liner film may be formed so as to cover the inner surface of the trench 120 and a polysilazane film may be formed in the trench 120. Alternatively, as the insulating layer 124, a silicon oxide film may be directly formed in the trench 120 by a film forming method such as a CVD method.

As illustrated in FIG. 18E, overall etching is performed by, for example, an RIE method until the insulating layer 124 in a region corresponding to the region in which the channel semiconductor layer is formed is removed. Then, the liner film 122B is formed so as to cover the inner surface of the trench 120 having the insulating layer 124 formed to the middle thereof. For example, an insulating film, such as a silicon oxide film which has a thickness of several nanometers and does not include an impurity or includes a little impurity, may be used as the liner film 122A. In addition, the liner film 122A can be formed by a film forming method such as a CVD method.

The diffusion source layer 125 with a higher P-type impurity concentration than the silicon substrate 110 is formed on the liner film 122B. The diffusion source layer 125 is formed such that it is embedded in the trench 120 whose inner surface is covered with the liner film 122B and is higher than the upper surface of the charge trapping layer 132. For example, a silicon oxide film including B may be used as the diffusion source layer 125. In addition, the diffusion source layer 125 can be formed by a film forming method such as a CVD method.

The diffusion source layer 125 functions as a P-type impurity diffusion source from which a P-type impurity is diffused to the silicon substrate 110 by a heat treatment which is performed in the subsequent process to form a channel semiconductor layer in a region around the diffusion source layer 125. The P-type impurity concentration of the diffusion source layer 125 is calculated in advance by experiments such that a channel semiconductor layer with desired concentration is finally obtained by diffusion.

As illustrated in FIG. 18F, for example, anisotropic etching is performed until the height of the upper surface of the diffusion source layer 125 in the trench 120 is substantially equal to that of the surface of the silicon substrate 110 by, for example, an RIE method. In this way, the diffusion source layer 125 remains in a region of the trench 120 corresponding to the region in which the channel semiconductor layer is formed in the vicinity of the upper part of the silicon substrate 110.

As illustrated in FIG. 18G, the insulating layer 126, which is a silicon oxide film without an impurity or with a little impurity, is formed in the trench 120 from which the liner film 122B and the upper surface of the diffusion source layer 125 are exposed so as to be higher than the upper surface of the charge trapping layer 132. As the insulating layer 126, for example, after a liner film may be formed so as to cover the inner surface of the trench 120 and a polysilazane film may be formed so as to embed in the trench 120. Alternatively, as the insulating layer 126, a silicon oxide film may be formed so as to directly embed in the trench 120 by a film forming method such as a CVD method.

As illustrated in FIG. 18H, overall etching is performed by, for example, an RIE method such that the upper surface of the insulating layer 126 in the trench 120 is higher than the interface between the gate insulating film 131 and the charge trapping layer 132. Then, the gate insulating film 133 and the control gate electrode 134 are sequentially formed.

The NAND-type flash memory device illustrated in FIG. 1, FIG. 16, and FIG. 17 in which the word lines WL extend in the X direction and are arranged at a predetermined interval in the Y direction is obtained by the same manufacturing process as that for the general NAND-type flash memory device. In the heat treatment process performed in this case, when the P-type impurity is diffused from the diffusion source layers 123 and 125 to the silicon substrate 110, the punch-through suppression layer 112 is formed around the diffusion source layer 123 and the channel semiconductor layer 111 is formed around the diffusion source layer 125.

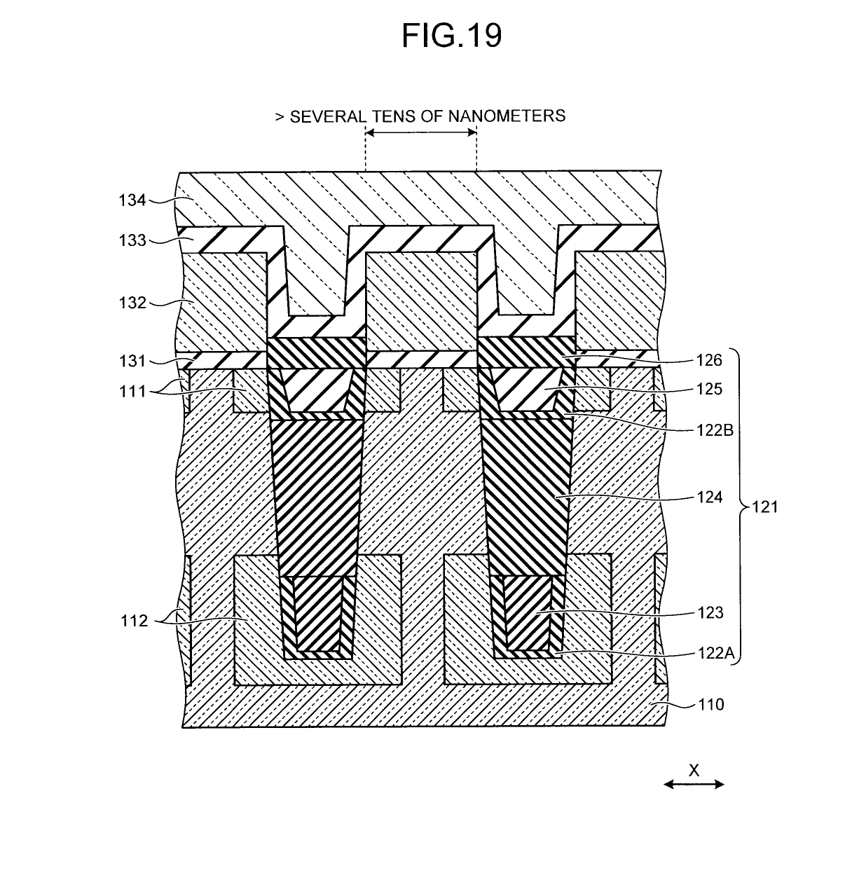

There is a limitation in the distance of the P-type impurity diffused from the diffusion source layers 123 and 125 by the heat treatment performed in the subsequent process. Therefore, it is difficult to apply the embodiment to the NAND-type flash memory devices with all sizes in a half pitch which is the width (the width of the channel semiconductor layer 111) of the memory cell in the X direction and the width of the STI 121. FIG. 19 is a cross-sectional view schematically illustrating the structure of a NAND-type flash memory device when diffusion is not sufficient. As illustrated in FIG. 19, the punch-through suppression layer 112 is formed such that punch-through can be suppressed by the diffusion of the P-type impurity from the diffusion source layer 123 which is embedded in the STI 121. However, the diffusion of the P-type impurity from the diffusion source layer 125 is insufficient and the channel semiconductor layers 111 which are formed by the diffusion source layers 125 adjacent to each other in the X direction do not contact each other. In this state, the function of the channel semiconductor layer 111 does not operate. As illustrated in FIG. 17, it is preferable that the half pitch be equal to or less than several tens of nanometers (for example, 30 nm) when the impurity diffusion layers which are formed by the P-type impurity diffused from both side diffusion source layers 125 overlap each other to form the channel semiconductor layer 111 in the upper part of the silicon substrate 110 between the STIs 121 adjacent to each other in the X direction. When the half pitch is greater than several tens of nanometers, the diffusion of impurities from the diffusion source layers 123 and 125 is insufficient as illustrated in FIG. 19, which makes it difficult to form the channel semiconductor layer 111.

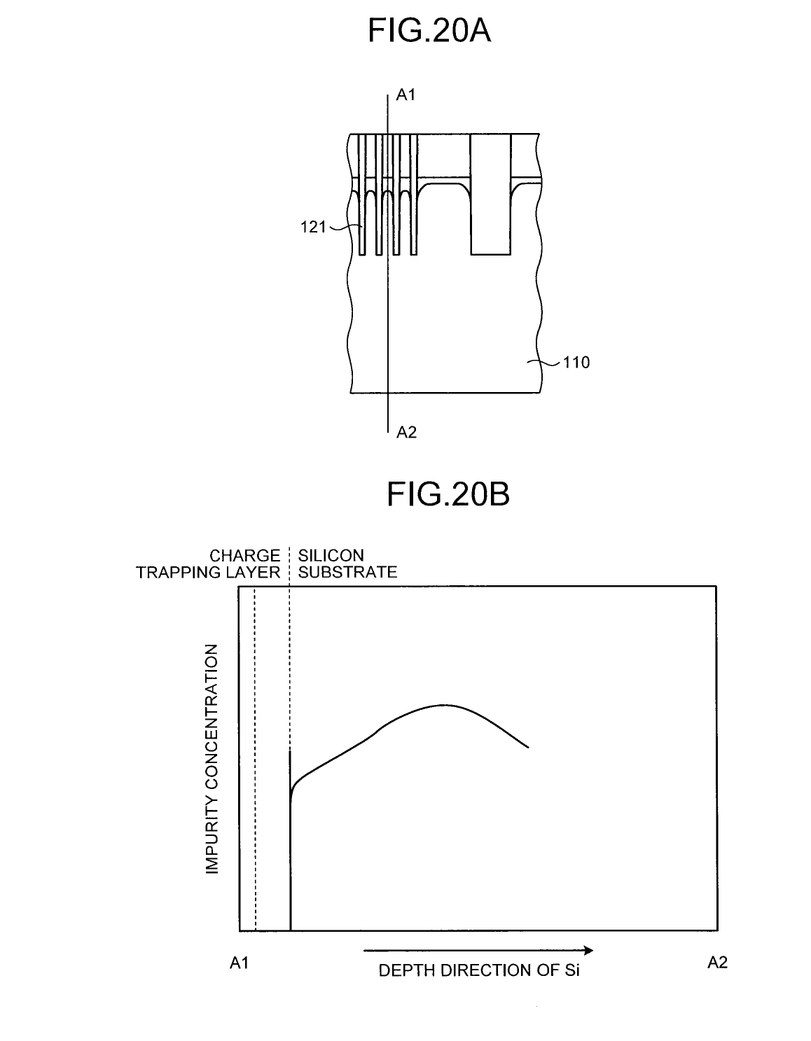

FIGS. 20A and 20B are diagrams illustrating an example of the simulation result of an impurity concentration distribution when the channel semiconductor layer and the punch-through suppression layer are formed by an ion implantation method and a thermal diffusion method. FIG. 20A is a diagram illustrating an example of the aspect of the impurity distribution in the cross-section of the NAND-type flash memory device and FIG. 20B is an example of the profile of impurities taken along the line A1-A2 of FIG. 20A. As illustrated in FIGS. 20A and 20B, when the P-type impurity is diffused to the silicon substrate 110 by the ion implantation method and the thermal diffusion method, the impurity is diffused by a heat treatment after ion implantation. Therefore, the impurity concentration distribution has a flat shape.

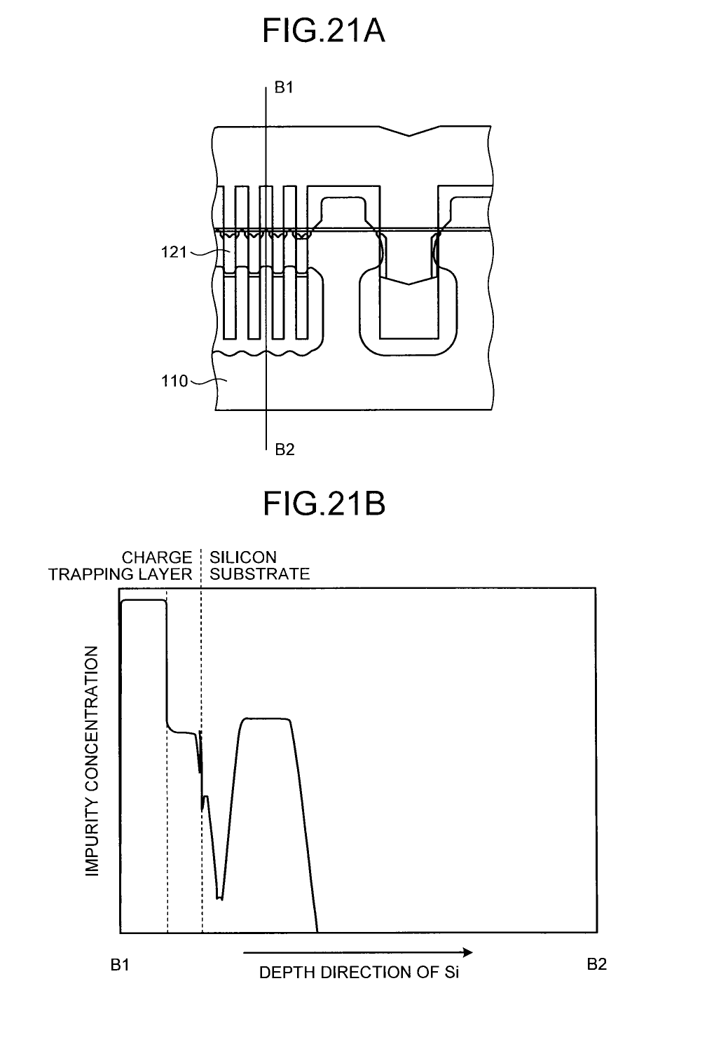

FIGS. 21A and 21B are diagrams illustrating an example of the simulation result of an impurity concentration distribution when the channel semiconductor layer and the punch-through suppression layer are formed by the method according to the embodiment. FIG. 21A is a diagram illustrating an example of the aspect of an impurity distribution in the cross-section of the NAND-type flash memory device and FIG. 21B is a diagram illustrating an example of the profile of impurities taken along the line B1-B2 of FIG. 21A. As illustrated in FIGS. 21A and 21B, when the P-type impurity is diffused to the silicon substrate 110 by the method according to the embodiment, it is possible to obtain an impurity concentration distribution which varies precipitously at the interface between the layers.

As described above, in this embodiment, the diffusion source layer 123 including the P-type impurity is provided in the vicinity of the bottom of the STI 121 and the diffusion source layer 125 including the P-type impurity is provided in the vicinity of the upper part of the silicon substrate 110. In this way, when the P-type impurity is diffused from the diffusion source layers 123 and 125 to the silicon substrate 110 by heat applied in the semiconductor device manufacturing process, the punch-through suppression layer 112 and the channel semiconductor layer 111 are respectively formed in regions corresponding to the regions in which the diffusion source layers 123 and 125 are formed and the impurity concentration distribution varies precipitously at the interface between each layer and the silicon substrate 110. As a result, it is possible to obtain a semiconductor device with good characteristics.

In addition, when the STI is formed after the punch-through suppression layer is formed at a predetermined depth in the silicon substrate, in some cases, the bottom of the STI does not reach the punch-through suppression layer or it passes through the punch-through suppression layer due to a variation in the processing of the STI. As a result, the function of the punch-through suppression layer does not operate. In addition, punch-through occurs between adjacent elements and the assumed element operation is not obtained. In contrast, in this embodiment, the diffusion source layer 123 is embedded in the bottom of the trench 120 for forming the STI 121 and the P-type impurity is diffused from the diffusion source layer 123 to the silicon substrate 110. Therefore, it is possible to form the punch-through suppression layer 112 at a position corresponding to the bottom of the STI 121, while preventing the bottom of the STI 121 from not reaching the punch-through suppression layer 112 or while preventing the bottom of the STI 121 from passing through the punch-through suppression layer 112. As a result, punch-through between adjacent elements is prevented and it is possible to perform the assumed element operation. That is, it is possible to diffuse impurities in correspondence with a variation in the processing of the trench 120 for forming the STI 121 and the effect of preventing punch-through is not affected by the variation in the processing of the trench 120.

In the above-described embodiment, the NAND-type flash memory device is given as an example, but the invention is not limited thereto. This embodiment can be applied to other semiconductor devices with the structure in which the diffusion layer is formed at a predetermined depth in the semiconductor substrate. In the above-described embodiment, the single-crystalline silicon substrate 110 is given as an example of the semiconductor substrate, but the semiconductor substrate is not limited thereto. For example, a polycrystalline silicon substrate or other single-crystalline or polycrystalline semiconductor substrates may be used.

In the above-described embodiment, the P-type channel semiconductor layer 111 and the P-type punch-through suppression layer 112 are formed on the P-type semiconductor substrate or in the P-type well including the N-channel field effect transistor. However, this embodiment can also be applied to a case in which an N-type channel semiconductor layer and an N-type punch-through suppression layer are formed on an N-type semiconductor substrate or in an N-type well including a P-channel field effect transistor.

In the above-described embodiment, the channel semiconductor layer 111 and the punch-through suppression layer 112 are formed. However, this embodiment can also be applied to all cases in which a plurality of layers having regions with different impurity concentrations is formed in the depth direction of the semiconductor substrate.

In the above-described embodiment, the liner films 122A and 122B are formed between the diffusion source layers 123 and 125 and the silicon substrate 110. However, the formation of the liner films 122A and 122B may be omitted. However, the liner films 122A and 122B may be provided in order to obtain the impurity concentration distribution which varies precipitously at the interface between the layers.

The embodiments have been described above with reference to the detailed examples. However, the embodiments are not limited to the detailed examples. That is, structures obtained by appropriately change the design of the examples by those skilled in the art are also included in the range of the embodiments as long as they have the characteristics of the embodiments. The components, the arrangement thereof, materials, conditions, shapes, and sizes in the above-mentioned detailed examples are not limited to the above, but may be appropriately changed.

The components in the above-described embodiments can be combined with each other as long as the combinations are technically available. The combinations are also included in the scope of the embodiments as long as they include the characteristics of the embodiments. In addition, it will be understood by those skilled in the art that various modifications and changes of the invention can be made without departing from the scope and spirit of the embodiments and the modifications and changes are also included in the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a plurality of first semiconductor regions that extend in a first direction and are arranged in a direction intersecting the first direction; and
an element separation region that is provided between the plurality of first semiconductor regions,
wherein the element separation region includes:
a first element separation portion that is formed to a first depth from an upper surface of the first semiconductor region; and
a second element separation portion that is formed from the first depth to a second depth more than the first depth and electrically insulates between adjacent elements.

2. The semiconductor device according to claim 1, further comprising:
a plurality of control gate electrodes that are provided above the plurality of first semiconductor regions, extend in a second direction different from the first direction, and are arranged in a direction intersecting the second direction;
a charge trapping layer that is provided at intersections of the plurality of first semiconductor regions and the plurality of control gate electrodes;
a first gate insulating film that is provided between the charge trapping layer and each of the plurality of first semiconductor regions; and
a second gate insulating film that is provided between the charge trapping layer and each of the plurality of control gate electrodes,
wherein the width of the second element separation portion in the second direction at a position where the first element separation portion is connected to the second element separation portion is less than the width of the first element separation portion in the second direction at the position.

3. The semiconductor device according to claim 2, further comprising:
a second semiconductor region that covers at least a portion of a lower end of the element separation region and a side surface of the element separation region connected to the lower end,
wherein the conduction type of the second semiconductor region is different from that of the plurality of first semiconductor regions.

4. The semiconductor device according to claim 2,
wherein the first element separation portion and the second element separation portion are made of the same insulating material.

5. The semiconductor device according to claim 2,
wherein the first element separation portion includes a first insulating film that covers the side surfaces of the first semiconductor region, the first gate insulating film, and the charge trapping layer in a first trench, and a second insulating film that covers a region other than the region in which the first insulating film and is made of a material different from the first insulating film, and
the second element separation portion includes a third insulating film that fills an entire second trench, and the third insulating film is made of a same material as the first insulating film.

6. The semiconductor device according to claim 3,
wherein the second element separation portion is made of an insulating material including an impurity of the same conduction type as an impurity in the second semiconductor region.

7. The semiconductor device according to claim 1,
wherein the first semiconductor region includes:
a first impurity diffusion layer which is formed from the first depth to the second depth and in which an impurity with a predetermined conduction type is diffused; and
a second impurity diffusion layer which is formed from an upper surface of the first semiconductor region to a third depth less than the first depth and in which an impurity with a predetermined conduction type is diffused, and
the element separation region includes:
a first diffusion source layer which is an insulating film that is provided from the first depth to the second depth and includes an impurity of the same conduction type as the impurity in the first impurity diffusion layer at a first concentration; and
a second diffusion source layer which is an insulating film that is provided from the upper surface of the first semiconductor region to the third depth and includes an impurity of the same conduction type as the impurity in the second impurity diffusion layer at a second concentration.

8. The semiconductor device according to claim 7,
wherein the first semiconductor region further includes a third impurity diffusion layer which is provided between the first impurity diffusion layer and the second impurity diffusion layer and in which an impurity of a predetermined conduction type is diffused in a region below the second impurity diffusion layer.

9. The semiconductor device according to claim 7, further comprising:
a first insulating film that is provided between the first diffusion source layer and the first semiconductor region and does not include the impurity or includes the impurity at a concentration less than the first diffusion source layer; and
a second insulating film that is provided between the second diffusion source layer and the first semiconductor region and does not include the impurity or includes the impurity at a concentration less than the second diffusion source layer.

10. The semiconductor device according to claim 7, further comprising:
a plurality of control gate electrodes that are provided above the plurality of first semiconductor regions, extend in a second direction different from the first direction, and are arranged in a direction intersecting the second direction;
a charge trapping layer that is provided at intersections of the plurality of first semiconductor regions and the plurality of control gate electrodes;
a first gate insulating film that is provided between the charge trapping layer and each of the plurality of first semiconductor regions; and
a second gate insulating film that is provided between the charge trapping layer and each of the plurality of control gate electrodes.

11. The semiconductor device according to claim 10,
wherein the element separation regions are higher than an interface between the first gate insulating film and the charge trapping layer, extend from a position lower than an upper surface of the charge trapping layer to at least the second impurity diffusion layer in the first direction.

12. A method of manufacturing a semiconductor device comprising:
forming a plurality of mask layers that extend in a first direction and are arranged in a direction intersecting the first direction on a stacked body including a semiconductor layer of a first conduction type, a first gate insulating film provided on the semiconductor layer, and a charge trapping layer provided on the first gate insulating film;
performing a first etching process to a portion of the stacked body exposed from the plurality of mask layers to form a plurality of first trenches which extend in the first direction in the semiconductor layer and to form each first semiconductor region interposed between the plurality of first trenches;
forming a first insulating layer on a side surface of the first semiconductor region interposed between the plurality of first trenches, a side surface of the first gate insulating film, and a side surface of the charge trapping layer;
performing a second etching process to the semiconductor layer below the bottom of each of the plurality of first trenches to lower the bottom of each of the plurality of first trenches, to form a second trench; and
forming a second insulating layer in each of the plurality of first and second trenches to form an element separation region including the first insulating layer and the second insulating layer in each of the plurality of first and second trenches.

13. The method of manufacturing the semiconductor device according to claim 12, further comprising:
introducing, after the second trenches are formed, an impurity element of a second conduction type from a portion of the bottom of each of the plurality of second trenches and the side surface of each of the plurality of second trenches which is connected to the semiconductor layer to form a second semiconductor region of the second conduction type between the portion of the bottom and the side surface of each of the plurality of second trenches and the first semiconductor region.

14. The method of manufacturing the semiconductor device according to claim 13,
wherein the second semiconductor region of the second conduction type is formed by introducing an impurity element of the second conduction type to the semiconductor layer using ion implantation

15. The method of manufacturing the semiconductor device according to claim 13,
wherein, in the formation of the second insulating layer, the second insulating layer including the impurity element of the second conduction type is formed in each of the plurality of second trenches, and
the impurity element of the second conduction type is diffused from the second insulating layer to the semiconductor layer.

16. A method of manufacturing a semiconductor device, comprising:
forming a trench in a semiconductor substrate;
forming a first insulating film so as to cover an inner surface of the trench;
forming a first diffusion source layer, which is an insulating film including an impurity of a predetermined conduction type at a first concentration, in the trench covered with the first insulating film;
performing etching to the first insulating film and the first diffusion source layer such that the first diffusion source layer remains in a region with a first depth;
embedding a second insulating film which does not include the impurity or includes the impurity at a concentration less than the first diffusion source layer to a second depth in the trench in which the first insulating film and the first diffusion source layer have been formed;
forming a third insulating film so as to cover the inner surface of the trench in which the second insulating film has been formed;
forming a second diffusion source layer, which is an insulating film including an impurity of a predetermined conduction type at a second concentration, in the trench covered with the third insulating film;
performing etching to the third insulating film and the second diffusion source layer such that the second diffusion source layer with a predetermined thickness from a second depth remains in the trench; and
embedding a fourth insulating film which does not include the impurity or includes the impurity at a concentration less than the second diffusion source layer in the trench in which the third insulating film and the second diffusion source layer have been formed.

17. The method of manufacturing the semiconductor device according to claim 16, further comprising:
performing, after the fourth insulating film is embedded, a heat treatment.

18. The method of manufacturing the semiconductor device according to claim 16,
wherein, in the formation of the trench, after a first gate insulating film and a charge trapping layer are formed on the semiconductor substrate, the trench which extends from an upper surface of the charge trapping layer to the semiconductor substrate in a first direction and is arranged in a second direction intersecting the first direction is formed, and
in the etching to the third insulating film and the second diffusion source layer, the etching is performed until the height of an upper surface of the second diffusion source layer is substantially equal to that of a surface of the semiconductor substrate.

19. The method of manufacturing the semiconductor device according to claim 18,
wherein, in the embedding of the fourth insulating film, the fourth insulating film is embedded in the trench such that an upper surface of the fourth insulating film is higher than an interface between the first gate insulating film and the charge trapping layer,
the method further comprising:
forming, after the fourth insulating film is embedded, a second gate insulating film so as to cover the charge trapping layer and the inner surface of the trench in which the fourth insulating film is formed;
forming a control gate electrode on the second gate insulating film; and
processing a region from the control gate electrode to the charge trapping layer such that the control gate electrode extends in the second direction and is arranged in the first direction.
